(19) United States
(12) Patent Application Publication
(10) Pub. No.: US 2023/0309367 A1
(43) Pub. Date: Sep. 28, 2023

(54) METHOD OF MANUFACTURING DISPLAY DEVICE AND MOTHER SUBSTRATE

(71) Applicant: Japan Display Inc., Tokyo (JP)

(72) Inventor: Hiroshi TABATAKE, Tokyo (JP)

(73) Assignee: Japan Display Inc., Tokyo (JP)

(21) Appl. No.: 18/189,247

(22) Filed: Mar. 24, 2023

(30) Foreign Application Priority Data
Mar. 25, 2022 (JP) 2022-050359

(51) Int. Cl. H10K 59/80; H10K 77/10; H10K 59/12; H10K 71/00

(52) U.S. Cl. CPC H10K 77/10; H10K 59/1201; H10K 59/871; H10K 59/8792; H10K 71/851

(57) ABSTRACT

According to one embodiment, a method of manufacturing a display device, includes forming a partition including a lower portion disposed on a first surface of a base and an upper portion protruding from a side surface of the lower portion, and measuring the distance between a side surface of the lower portion and an end portion of the upper portion from a side of a second surface opposing the first surface of the base.

### CROSS-REFERENCE TO RELATED APPLICATIONS

This application is based upon and claims the benefit of priority from Japanese Patent Application No. 2022-050359, filed Mar. 25, 2022, the entire contents of which are incorporated herein by reference.

### FIELD

Embodiments described herein relate generally to a method for manufacturing a display device and a mother substrate.

### BACKGROUND

In recent years, a display device in which an organic light-emitting diode (OLED) is applied as a display element has been put to practical use.

Here, the above-mentioned display device is manufactured by the following manner. That is, a mother base is prepared by forming a plurality of base all together at once, and a plurality of display panels are formed on the mother base, thus preparing a mother substrate. Then, display panels are cut from the mother substrate, and each of which is used for manufacturing the display device.

In the process of manufacturing such a display device, such a technology is required to suppress the degradation of reliability of the display device.

### BRIEF DESCRIPTION OF THE DRAWINGS

FIG. 1 is a diagram showing a configuration example of a display device according to an embodiment.

FIG. 2 is a diagram showing an example of layout of subpixels.

FIG. 3 is a cross-sectional view schematically showing the display device, taken along line III-III in FIG. 2.

FIG. 4 is a cross-sectional view schematically showing a partition.

FIG. 5 is a cross-sectional view schematically illustrating a display element formed by using a partition.

FIG. 6 is a cross-sectional view schematically illustrating a display element formed by using a partition.

FIG. 7 is a cross-sectional view schematically illustrating a display element formed by using a partition.

FIG. 8 is a diagram for illustrating measurement of a protrusion amount of a partition.

FIG. 9 is a diagram for illustrating measurement of the protrusion amount of a partition.

FIG. 10 is a diagram schematically showing a mother substrate.

FIG. 11 is a diagram schematically showing a method of manufacturing a display device.

FIG. 12 is a diagram showing an example of a pattern of partitions formed in a surrounding area.

FIG. 13 is a cross-sectional view schematically showing a surrounding area where a partition is formed directly above the mother base.

FIG. 14 is a cross-sectional view schematically showing a surrounding area where a first insulating layer and a partition are formed in sequence on a mother base.

FIG. 15 is a cross-sectional view schematically showing a surrounding area where a first insulating layer, a rib and a partition are formed in sequence on a mother base.

FIG. 16 is a cross-sectional view schematically showing a surrounding area where a first insulating layer, a second insulating layer and a partition are formed in sequence on a mother base.

### DETAILED DESCRIPTION

In general, according to one embodiment, a method of manufacturing a display device, includes forming a partition including a lower portion disposed on a first surface of a base and an upper portion protruding from a side surface of the lower portion, and measuring a distance between a side surface of the lower portion and an end portion of the upper portion from a side of a second surface opposing the first surface of the base.

Embodiments will be described hereinafter with reference to the accompanying drawings.

Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as a first direction, a direction along the Y axis is referred to as a second direction and a direction along the Z axis is referred to as a third direction. Further, viewing the elements parallel to the third direction Z is referred to as plan view.

The display device in this embodiment is an organic electroluminescent display device comprising an organic light-emitting diode (OLED) as a display element, and can be mounted on televisions, personal computers, in-vehicle devices, tablet terminals, smartphones, mobile cell phone terminal and the like.

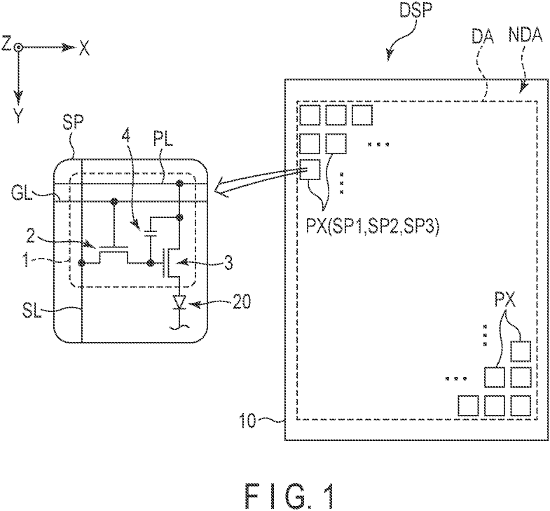

FIG. 1 shows a configuration example of the display device DSP in this embodiment. The display device DSP includes a display area DA which displays images and a non-display area NDA surrounding the display area DA on an insulating base 10. The base 10 may be glass or a flexible resin film.

In this embodiment, the shape of the base 10 in plan view is rectangular. Note here that the shape of the base 10 in plan view is not limited to a rectangle, but may be other shapes such as a square, circle or oval.

The display area DA comprises a plurality of pixels PX arranged in a matrix along the first direction X and the second direction Y. The pixels PX each include a plurality of subpixels SP. For example, the pixels PX each include a red subpixel SP1, a green subpixel SP2 and a blue subpixel SP3. Note that the pixels PX may each include, in addition to the subpixels SP1, SP2 and SP3, a subpixel SP of some other color such as white. Or, the pixels PX may each include subpixels SP of other colors in place of any of the subpixels SP1, SP2 and SP3.

The subpixels SP each comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are switching elements constituted by thin-film transistors, for example.

A gate electrode of the pixel switch 2 is connected to a scanning line GL. One of source and drain electrodes of the pixel switch 2 is connected to a signal line SL, and the other is connected to a gate electrode of the drive transistor 3 and the capacitor 4. In the drive transistor 3, one of source and drain electrodes is connected to a power line PL and capacitor 4, and the other is connected to the display element 20.

The configuration of the pixel circuit 1 is not limited to that of the example shown in FIG. 1. For example, the pixel circuit 1 may comprise more thin-film transistors and capacitors.

The display element 20 is an organic light-emitting diode (OLED) as a light emitting element. For example, the subpixel SP1 contains a display element 20 which emits light in a wavelength range of a red color, the subpixel SP2 contains a display element 20 which emits light in a wavelength range of a green color, and the subpixel SP3 contains a display element 20 which emits light in a wavelength range of a blue color.

FIG. 1 mainly shows a display panel used for manufacturing a display device DSP, and the display device DSP has a structure in which a circuit board, etc., comprising a driver (drive IC chip) or the like to drive the display panel is connected to the display panel.

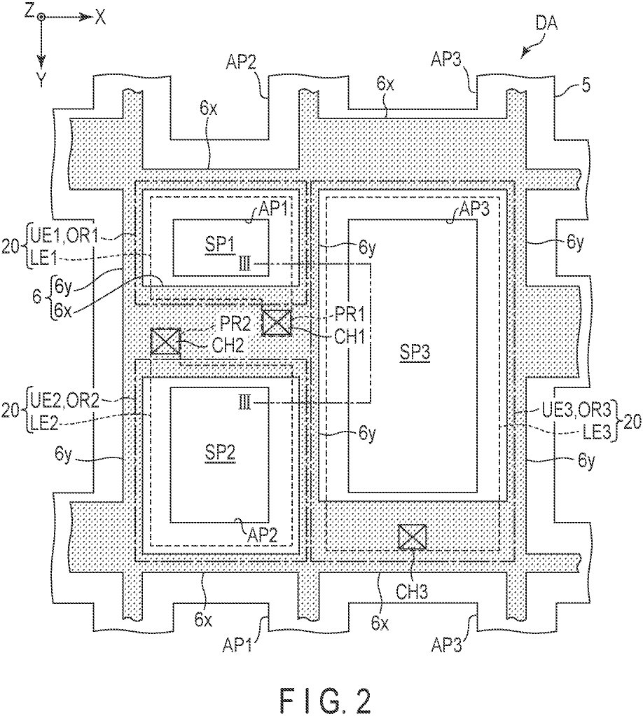

FIG. 2 shows an example of layout of subpixels SP1, SP2 and SP3. In the example illustrated in FIG. 2, the subpixels SP1 and SP2 are aligned along the second direction Y. Further, the subpixels SP1 and SP2 are each aligned with subpixel SP3 along the first direction X.

When the subpixels SP1, SP2 and SP3 are arranged in such a layout as shown in FIG. 2, rows in each of which the subpixels SP1 and SP2 are arranged alternately along the second direction Y and rows in each of which a plurality of subpixels SP3 are arranged repeatedly along the second direction Y are formed in the display area DA. These rows are alternately arranged along the first direction X.

The layout of the subpixels SP1, SP2 and SP3 is not limited to that of the example shown in FIG. 2. As another example, the subpixels SP1, SP2 and SP3 in each pixel PX may be arranged in order along the first direction X.

In the display area DA, a Rib 5 and a partition 6 are disposed. The rib 5 includes apertures AP1, AP2 and AP3 in the subpixels SP1, SP2 and SP3, respectively. In the example illustrated in FIG. 2, the apertures AP2 are larger in size than the apertures AP1, and the apertures AP3 are larger than the aperture AP2. The partition 6 is disposed at the boundaries of each adjacent pair of the subpixels SP and overlaps the rib 5 in plan view.

The partition 6 includes a plurality of first partitions 6x extending along the first direction X and a plurality of second partitions 6y extending along the second direction Y. The first partitions 6x are each disposed between each respective pair of apertures AP1 and AP2 adjacent to each other along the second direction Y and between each respective pair of apertures AP3 adjacent to each other along the second direction Y. The second partitions 6y are each disposed between each respective pair of apertures AP1 and AP3 adjacent to each other along the first direction X and between each respective pair of apertures AP2 and AP3 adjacent to each other along the second direction.

In the example illustrated in FIG. 2, the first partitions 6x and the second partitions 6y are connected to each other. With this structure, the partition 6 as a whole is formed into a lattice shape which surrounds the apertures AP1, AP2 and AP3. The partition 6 may as well include apertures in the subpixels SP1, SP2 and SP3, respectively, as in the case of the rib 5.

That is, in this embodiment, the rib 5 and the partition 6 are arranged to compartmentalize the subpixels SP1, SP2 and SP3 one from another.

The subpixels SP1 each comprises a lower electrode LE1, an upper electrode UE1 and an organic layer OR1, each of which overlap the respective aperture AP1. The subpixel SP2 each comprises a lower electrode LE2, an upper electrode UE2 and an organic layer OR2, each of which overlap the respective apertures AP2. The subpixels SP3 each comprises a lower electrode LE3, an upper electrode UE3 and an organic layer OR3, each of which overlap the respective aperture AP3. In the example illustrated in FIG. 2, the outlines of the upper electrode UE1 and the organic layer OR1 match each other, the outlines of the upper electrode UE2 and the organic layer OR2 match each other, and the outlines of the upper electrode UE3 and the organic layer OR match each other.

The lower electrode LE1, the upper electrode UE1 and the organic layer OR1 constitute the display element 20 of the subpixel SP1. The lower electrode LE2, the upper electrode UE2 and the organic layer OR2 constitute the display element 20 of the subpixel SP2. The lower electrode LE3, the upper electrode UE3 and the organic layer OR3 constitute the display element 20 of the subpixel SP3.

The lower electrode LE1 is connected to the pixel circuit 1 that drives the subpixel SP1 (the display element 20 thereof) via a contact hole CH1. The lower electrode LE2 is connected to the pixel circuit 1 that drives the subpixel SP2 (the display element 20 thereof) via a contact hole CH2. The lower electrode LE3 is connected to the pixel circuit 1 that drives the subpixel SP3 (the display element 20 thereof) via a contact hole CH3.

In the example illustrated in FIG. 2, the contact holes CH1 and CH2 entirely overlap the first partition 6x located between the apertures AP1 and AP2 adjacent to each other along the second direction Y. The contact hole CH3 entirely overlaps the first partition 6x located between two apertures AP3 adjacent to each other along the second direction Y. As another example, at least a part of the contact holes CH1, CH2 and CH3 may not overlap the first partition 6x.

In the example illustrated in FIG. 2, the lower electrodes LE1 and LE2 includes protrusions PR1 and PR2, respectively. The protrusion PR1 protrudes from the body of the lower electrode LE1(, which is a part overlapping the aperture AP1) toward the contact hole CH1. The protrusion PR2 protrudes from the body of the lower electrode LE2(, which is a part overlapping the aperture AP2) toward the contact hole CH2. The contact holes CH1 and CH2 overlap the protrusions PR1 and PR2, respectively.

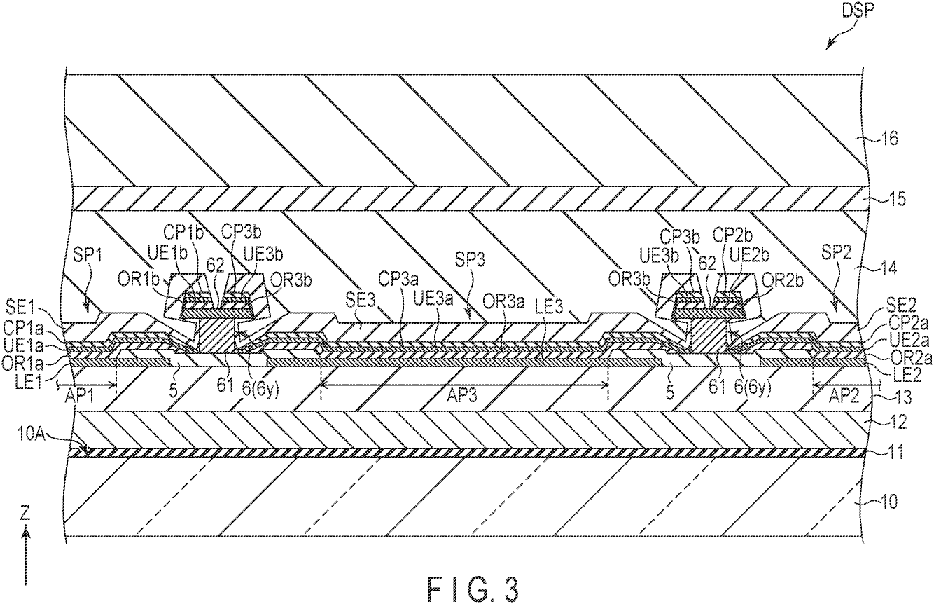

FIG. 3 is a schematic cross-sectional view of the display device DSP taken along line III-III in FIG. 2. In the display device DSP, an insulating layer 11, referred to as an undercoat layer, is disposed on a first surface 10A (a surface on a side where the display element 20 and the like are disposed) of the base 10 having light transparency, such as of glass described above.

The insulating layer 11 has a three-layer stacked structure including, for example, a silicon oxide film (SiO), a silicon nitride film (SiN) and a silicon oxide film (SiO). Note that the insulating layer 11 is not limited to a three-layer stacked structure, but may have a stacked structure of three or more layers, or may have a single-layer structure or a two-layer stacked structure.

On the insulating layer 11, a circuit layer 12 is disposed. The circuit layer 12 includes various types of circuits and wiring lines that drive the subpixels SP (SP1, SP2 and SP3) such as the pixel circuit 1, scanning line GL, signal line SL and power line PL shown in FIG. 1. The circuit layer 12 is covered by an insulating layer 13.

The insulating layer 13 functions as a planarization film that planarizes the unevenness caused by the circuit layer 12. Although not shown in FIG. 3, the contact holes CH1, CH2 and CH3 described above are provided in the insulating layer 13.

The lower electrodes LE (LE1, LE2 and LE3) are disposed on the insulating layer 13. The rib 5 is disposed over the insulating layer 13 and the lower electrode LE. An end portion (a part) of the lower electrode LE is covered by the rib 5.

The partition 6 includes a lower portion 61 disposed on the rib 5 and an upper portion 62 covering an upper surface of the lower portion 61. The upper portion 62 has a width greater than that of the lower portion 61. With this configuration, the partition 6 has such a shape that both ends of the upper portion 62 protrude beyond side surfaces of the lower portion 61. Such a shape of the partition 6 may as well be referred to as an overhang shape.

The organic layers OR (OR1, OR2 and OR3) and the upper electrodes UE (UE1, UE2 and UE3) constitute the display elements 20, respectively, together with the lower electrodes LE (LE1, LE2 and LE3) described above. Here, as shown in FIG. 3, the organic layer OR1 includes a first organic layer OR1a and a second organic layer OR1b spaced apart from each other. The upper electrode UE1 includes a first upper electrode UE1a and a second upper electrode UE1b spaced apart from each other. The first organic layer OR1a is in contact with the lower electrode LE1 via the aperture AP1, and covers a part of the rib 5 as well. The second organic layer OR1b is located on the upper portion 62. The first upper electrode UE1a opposes the lower electrode LE1 and covers the first organic layer OR1a. Further, the first upper electrode UE1a is in contact with a side surface of the lower portion 61. The second upper electrode UE1b is located above the partition 6 and covers the second organic layer OR1b.

Moreover, as shown in FIG. 3, the organic layer OR2 includes a first organic layer OR2a and a second organic layer OR2b spaced apart from each other. The upper electrode UE2 includes a first upper electrode UE2a and a second upper electrode UE2b spaced apart from each other. The first organic layer OR2a is in contact with the lower electrode LE2 via the aperture AP2 and covers a part of the rib 5. The second organic layer OR2b is located on the upper portion 62. The first upper electrode UE2a opposed the lower electrode LE2 and covers the first organic layer OR2a. Further, the first upper electrode UE2a is in contact with the side surface of the lower portion 61. The second upper electrode UE2b is located above the partition 6 and covers the second organic layer OR2b.

As shown in FIG. 3, the organic layer OR3 includes a first organic layer OR3a and a second organic layer OR3b spaced apart from each other. The upper electrode UE3 includes a first upper electrode UE3a and a second upper electrode UE3b spaced apart from each other. The first organic layer OR3a is in contact with the lower electrode LE3 via the aperture AP3 and covers a part of the rib 5. The second organic layer OR3b is located on the upper portion 62. The first upper electrode UE3a opposes the lower electrode LE3 and covers the first organic layer OR3a. Further, the first upper electrode UE3a is in contact with a side surface of the lower portion 61. The second upper electrode UE3b is located above the partition 6 and covers the second organic layer OR3b.

In the example illustrated in FIG. 3, the subpixels SP1, SP2 and SP3 include cap layers CP1, CP2 and CP3, respectively, for adjusting the optical properties of the light emitted by the light-emitting layers of the organic layers OR1, OR2 and OR3.

The cap layer CP1 includes a first cap layer CP1a and a second cap layer CP1b spaced apart from each other. The first cap layer CP1a is located in the aperture AP1 and disposed on the first upper electrode UE1a. The second cap layer CP1b is located above the partition 6 and disposed on the second upper electrode UE1b.

The cap layer CP2 includes a first cap layer CP2a and a second cap layer CP2b spaced apart from each other. The first cap layer CP2a is located in the aperture AP2 and disposed on the first upper electrode UE2a. The second cap layer CP2b is located above the partition 6 and disposed on the second upper electrode UE2b.

The cap layer CP3 includes a first cap layer CP3a and a second cap layer CP3b spaced apart from each other. The first cap layer CP3a is located in the aperture AP3 and disposed on the first upper electrode UE3a. The second cap layer CP3b is located above the partition 6 and disposed on the second upper electrode UE3b.

On the on subpixels SP1, SP2 and SP3, sealing layers SE1, SE2 and SE3 are disposed respectively. The sealing layer SE1 continuously covers members of the subpixel SP1, which include the first cap layer CP1a, the partition 6 and the second cap layer CP1b. The sealing layer SE2 continuously covers members of the subpixel SP2, which include the first cap layer CP2a, the partition 6 and the second cap layer CP2b. The sealing layer SE3 continuously covers members of the subpixel SP3, which include the first cap layer CP3a, the partition 6 and the second cap layer CP3b.

In the example illustrated in FIG. 3, the second organic layer OR1b, the second upper electrode UE1b, the second cap layer CP1b and the sealing layer SE1 on the partition 6 between the subpixels SP1 and SP3 are separated from the second organic layer OR3b, the second upper electrode UE3b, the second cap layer CP3b and the sealing layer SE3 on the partition 6. Further, the second organic layer OR2b, the second upper electrode UE2b, the second cap layer CP2b and the sealing layer SE2 on the partition 6 between the subpixels SP2 and SP3 are separated from the second organic layer OR3b, the second upper electrode UE3b, the second cap layer CP3b and the sealing layer SE3 on the partition 6.

The sealing layers SE1, SE2 and SE3 are covered by a resin layer 14. The resin layer 14 is covered by a sealing layer 15. Further, the sealing layer 15 is covered by a resin layer 16.

The insulating layer 13 and the resin layers 14 and 16 are formed of organic materials. The rib 5 and the sealing layer 15 and SE (SE1, SE2 and SE3) are formed of, for example, inorganic materials including silicon nitride (SiNx).

The lower portion 61 of the partition 6 has conductivity. The upper portion 62 of the partition 6 may as well be formed conductive. The lower electrode LE may be formed of a transparent conductive oxide such as indium tin oxide (ITO) or may have a multilayer stacked structure of a metal material such as silver (Ag) and a conductive oxide. The upper electrode UE is formed of a metal material such as an alloy of magnesium and silver (MgAg), for example. The upper electrode UE may as well be formed of a conductive oxide such as ITO.

When the potential of the lower electrode LE is relatively higher than that of the upper electrode UE, the lower electrode LE corresponds to an anode and the upper electrode UE corresponds to a cathode. Or, when the potential of the upper electrode UE is relatively higher than that of the lower electrode LE, the upper electrode UE corresponds to an anode and the lower electrode LE corresponds to a cathode.

The organic layer OR includes a pair of functional layers and a light-emitting layer disposed between these functional layers. For example, the organic layer OR has a structure in which a hole injection layer, a hole transport layer, an electron blocking layer, an emitting layer, a hole blocking layer, an electron transport layer and an electron injection layer are stacked one on another in order.

The cap layers CP (CP1, CP2 and CP3) are each formed, for example, from a multilayer body of a plurality of transparent thin films. The multilayer body may include, as the thin films, thin films formed of inorganic materials and thin films formed of organic materials. These thin films have refractive indices different from each other. The material of the thin films which constitute the multilayer body is different from the material of the upper electrode UE and also from the material of the sealing layers SE. Note here that the cap layers CP may be omitted.

To the partition 6, a common voltage is supplied. The common voltage is supplied to each of the upper electrodes UE (the first upper electrodes UE1a, UE2a and UE3a), which are in contact with the side surface of the lower portion 61. To the lower electrodes LE (LE1, LE2 and LE3), pixel voltages are supplied via the pixel circuits 1 of the subpixels SP (SP1, SP2 and SP3), respectively.

When a potential difference is created between the lower electrode LE1 and the upper electrode UE1, the light-emitting layer of the first organic layer OR1a emits light in a wavelength range of a red color. When a potential difference is created between the lower electrode LE2 and the upper electrode UE2, the light-emitting layer of the first organic layer OR2a emits light in a wavelength range of a green color. When a potential difference is created between the lower electrode LE3 and the upper electrode UE3, the light-emitting layer of the first organic layer OR3a emits light in a wavelength range of a blue color.

As another example, the light-emitting layers of the organic layers OR1, OR2 and OR3 may emit light of the same color (for example, white). In this case, the display device DSP may comprise color filters that convert the light emitted by the light-emitting layers into light of colors corresponding to the subpixels SP1, SP2 and SP3, respectively. Further, the display device DSP may comprise layers containing quantum dots that are excited by the light emitted by the light-emitting layers to generate light of colors corresponding to the subpixels SP1, SP2 and SP3, respectively.

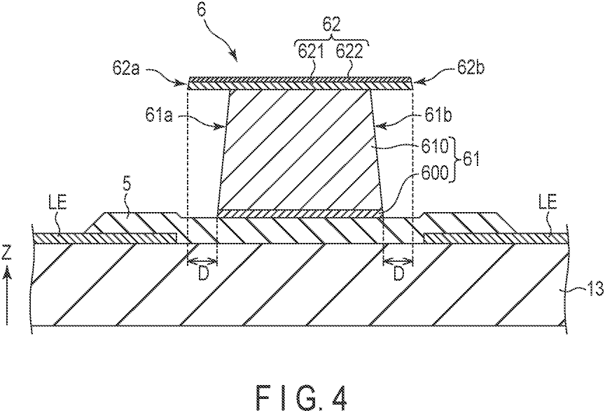

FIG. 4 is an enlarged cross-sectional view schematically showing the partition 6. In FIG. 4, elements other than the rib 5, the partition 6, the insulating layer 13 and the pair of lower electrodes LE are omitted from illustration. The pair of lower electrodes LE correspond to any of the lower electrodes LE1, LE2 and LE3 described above. The first partitions 6x and the second partitions 6y described above have the same structure as that of the partition 6 shown in FIG. 4.

In the example illustrated in FIG. 4, the lower portion 61 of the partition 6 includes a barrier layer 600 disposed on the rib 5 and a metal layer 610 disposed on the barrier layer 600. The barrier layer 600 is formed of a material different from that of the metal layer 610, that is, for example, a metal material such as molybdenum. The metal layer 610 is formed thicker than the barrier layer 600. The metal layer 610 may be of a single-layer structure or a stacked structure of different metallic materials. For example, the metal layer 610 is formed, for example, by aluminum (Al).

The upper portion 62 is thinner than the lower portion 61. In the example illustrated in FIG. 4, the upper portion 62 includes a first layer 621 disposed on the metal layer 610 and a second layer 622 disposed on the first layer 621. For example, the first layer 621 is formed of titanium (Ti), whereas the second layer 622 is formed of ITO, for example.

In the example illustrated in FIG. 4, the width of the lower portion 61 decreases as the location is closer to the upper portion 62. In other words, side surfaces 61a and 61b of the lower portion 61 are inclined with respect to the third direction Z. Note here that the upper portion 62 includes an end portion 62a protruding from the side surface 61a and an end portion 62b protruding from the side surface 61b.

Here, the amount of protrusion of the end portions 62a and 62b from the side surfaces 61a and 61b is represented by D(, which will be referred to as the protrusion amount D of the partition 6, hereinafter) and is, for example, 2.0 µm or less. The protrusion amount D of the partition 6 in this embodiment corresponds to the distance between a respective lower edge of the side surface 61a (the barrier layer 600) and the end portion 62a and between a respective lower edge of the side surface 61b (the barrier layer 600) and the end portion 62 along the width direction of the partition 6 (the first direction X or second direction Y), which is orthogonal to the third direction Z.

The configuration of the partition 6 and the material of each member of the partition 6 may be selected as appropriate in consideration of, for example, the method of forming the partition 6 and the like.

In this embodiment, the partition 6 is formed to compartmentalize the subpixels SP in plan view. Here, the organic layer OR described above is formed, for example, by an anisotropic or directional vacuum deposition method. When the organic material for forming the organic layer OR is deposited over the entire base 10 with the partition 6 disposed therein, the organic layer OR is not substantially formed on the side surface of the partition 6 because the partition 6 has such a shape as shown in FIGS. 3 and 4. In this manner, the organic layer OR (the display elements 20) can be formed such as to be divided into each subpixel SP by the partition 6.

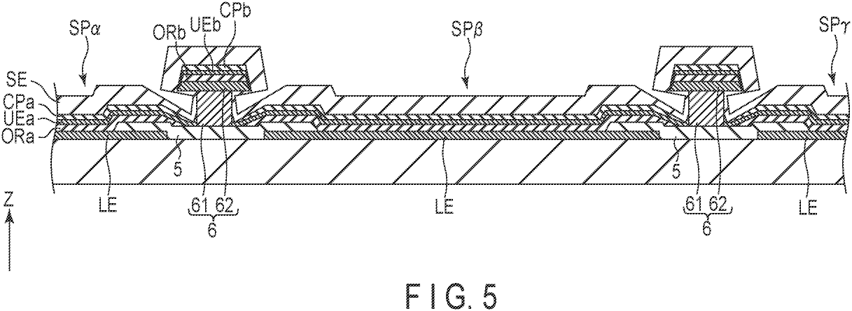

FIGS. 5 to 7 are each a schematic cross-sectional view to illustrate display elements 20 formed by using the partition 6. FIGS. 5 to 7 show subpixels SPα, SPβ and SPγ, which correspond to any of the subpixels SP1, SP2 and SP3.

With the partition 6 disposed as described above, the organic layer OR, the upper electrode UE, the cap layer CP and the sealing layer SE are formed by vapor deposition in order on the entire base 10 as shown in FIG. 5. The organic layer OR includes a light-emitting layer that emits light of a color corresponding to the subpixel SPα. With the overhanging partition 6, the organic layer OR is divided into a first organic layer ORa covering the lower electrode LE and a second organic layer ORb on the partition 6, the upper electrode UE is divided into a first upper electrode UEa covering the first organic layer ORa and a second upper electrode UEb covering the second organic layer ORb, and the cap layer CP is divided into a first cap layer CPa covering the first upper electrode UEa and a second cap layer CPb covering the second upper electrode UEb. The first upper electrode UEa is in contact with the lower portion 61 of the partition 6. The sealing layer SE continuously covers the first cap layer CPa, the second cap layer CPb and the partition 6.

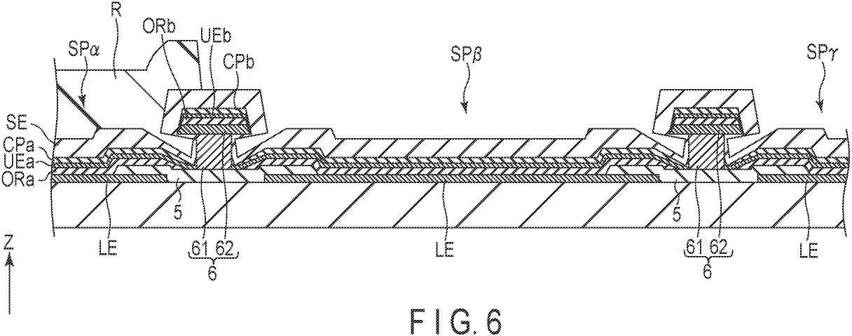

Next, as shown in FIG. 6, a resist R is formed on the sealing layer SE. The resist R covers the subpixel SPα. In other words, the resist R is disposed directly above the first organic layer ORa, the first upper electrode UEa and the first cap layer CPa, which are located in the subpixel SPα. The resist R is also located directly above the portion of the second organic layer ORb, the second upper electrode UEb and the second cap layer CPb on the partition 6 between the subpixel SPα and the subpixel SPβ, which is closer to the subpixel SPα. In other words, at least a part of the partition 6 is exposed from the resist R.

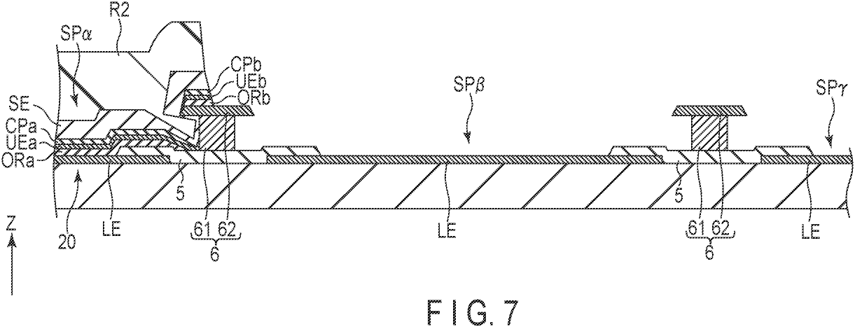

Further, by etching using the resist R as a mask, portions of the organic layer OR, the upper electrode UE, the cap layer CP and the sealing layer SE, which are exposed from the resist R are removed, as shown in FIG. 7. As a result, a display element 20 which includes the lower electrode LE, the first organic layer ORa, the first upper electrode UEa and the first cap layer CPa is formed in the subpixel SPα. On the other hand, in the subpixels SPβ and SPγ, the lower electrode LE is exposed. Note that the etching described above includes, for example, dry etching of the sealing layer SE, wet etching and dry etching of the cap layer CP, wet etching of the upper electrode UE, and dry etching of the organic layer OR.

After the display element 20 of the subpixel SPα is formed as described above, the resist R is removed and the display elements 20 of the subpixels SPβ and SPγ are formed in the same order as in the case of the subpixel SPα.

By exemplified above with respect to the subpixels SPα, SPβ and SPγ, the display elements 20 of the subpixels SP1, SP2 and SP3 are formed and further the resin layer 14, the sealing layer 15 and the resin layer 16 are formed, thereby realizing the configuration of the display device DSP shown in FIG. 3.

Here, as described above, the partition 6 includes the lower portion 61 and an upper portion 62 protruding from the side surfaces of the lower portion 61. If the protrusion amount D (eave width) of the partition 6 described above is not appropriate, the reliability of the display device DSP may be reduced.

More specifically, the display device DSP has such a structure that the organic layer OR is divided for each subpixel SP by the partition 6. With this structure, if the protrusion amount D is not sufficiently larger than the designed value, the organic layer OR may not be divided appropriately. Further, if the side surface of the lower portion 61 of the partition 6 is covered by the organic layer OR, the electrical connection between the lower portion 61 and the upper electrode UE is impeded. On the other hand, in the display device DSP, the upper electrode UE is in contact with the side surface of the lower portion 61 of the partition 6. Here, if the protrusion amount D of the partition 6 exceeds the designed value, the upper electrode UE may not be brought into contact with the side surface of the lower portion 61.

In other words, if the protrusion amount D of the above-mentioned partition 6 is not appropriate, a highly reliable display device DSP cannot be manufactured. Therefore, it is useful to measure the protrusion amount D (that is, the distance between the side surface of the lower portion 61 and the end portion of the upper portion 62 of the partition 6) in the manufacturing process of the display device DSP. Note that for the measurement of the protrusion amount D of the partition 6, for example, a length-measuring machine camera can be used, which is configured to measure, by capturing an image including an object, the length of the object.

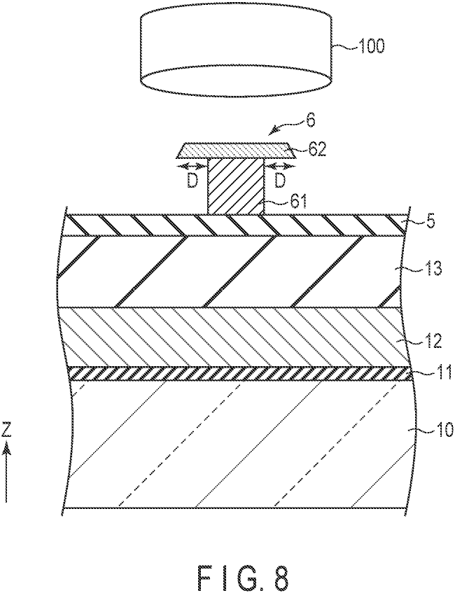

Here, as shown in FIG. 8, let us assume the case where the protrusion amount D of the partition 6 is measured by capturing the image of the partition 6 from the third direction Z (that is, from a side of the display surface of the display device DSP) using the length-measuring machine camera 100 at the stage where the partition 6 is formed. In this case, the upper portion 62 of the partition 6 has a width larger than that of the lower portion 61 (in other words, the partition 6 has the overhang shape). With this structure, for example, if the upper portion 62 contains a layer formed of a light-shielding metal material (for example, titanium) that has no light transparency, the side surface of the lower portion 61 (that is, the end portion of the lower portion 61 along the first direction X or the second direction Y) cannot be shot by the length-measuring machine camera 100. That is, in the example shown in FIG. 8, the length (width) of the upper portion 62 along the first direction X or the second direction Y can be measured, but the protrusion amount D of the partition 6 cannot be measured.

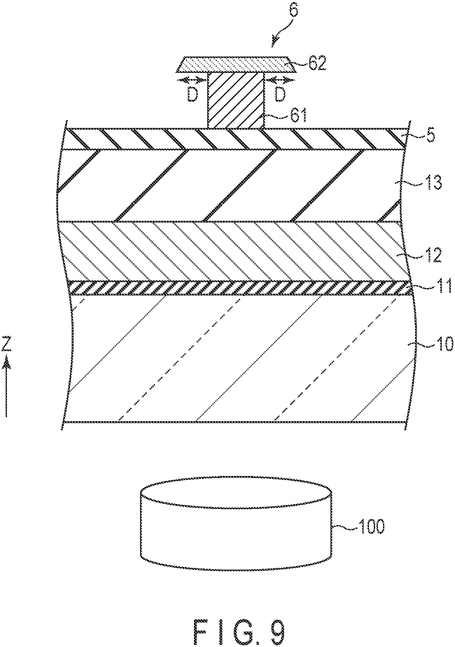

Therefore, as shown in FIG. 9, in this embodiment, the protrusion amount D of the partition 6 is measured by capturing the image of the partition 6 from a direction opposite to the third direction Z (that is, from a side of a rear surface opposite to the display surface of the display device DSP) using the length-measuring machine camera 100. With this configuration, the length-measuring machine camera 100 can capture the image of the end portion of each of the lower portion 61 and the upper portion 62 along the first direction X or the second direction Y, and thus it is considered that the protrusion amount D of the partition 6 can be measured.

However, as described above, in the display device DSP, the circuit layer 12 (various circuits and wiring lines) and the insulating layer 13 that is relatively thick are disposed on the base 10 and the insulating layer 11. Therefore, even if an image of the partition 6 is captured from a direction opposite to the third direction Z using the length-measuring machine camera 100, the protrusion amount D of the partition 6 may not be properly measured due to the influence of the circuit layer 12, etc.

Incidentally, generally, in the manufacturing process of a display device DSP, a mother substrate is manufactured, on which a plurality of display panels are formed on a mother base in which a plurality of bases 10 are formed at once. Then, each of the display panels cut from the mother substrate, and using this display panel, the display device DSP is thus manufactured.

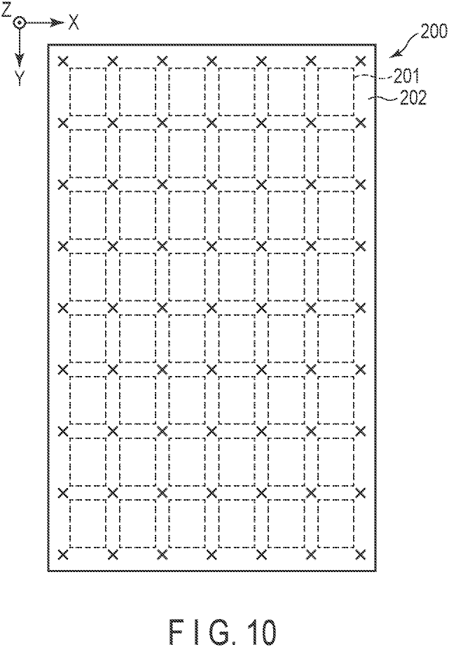

FIG. 10 schematically shows a mother substrate (mother base). As shown in FIG. 10, a mother substrate 200 includes a plurality of panel regions 201 and a peripheral area 202. The size of the mother substrate 200 is about 1500 mm × 950 mm, for example, but the size is not limited to this.

The panel regions 201 are each a region where a display panel is formed and are arranged in a matrix along the first direction X and the second direction Y. The peripheral region 202 is a region that is located around the panel regions 201 and compartmentalize the plurality of panel regions 201 from each other.

Here, the display panels respectively formed in the panel regions 201 include a circuit layer 12 as illustrated in FIG. 3 and the like. With this configuration, it is not appropriate to capture the image of the partition 6 in each panel region 201 (that is, to measure the protrusion amount D of the partition 6) using the length-measuring machine camera 100.

For this reason, in this embodiment, the protrusion amount D of the partition 6 will be measured by utilizing the peripheral region 202 (that is, the region marked with “×” in FIG. 10, for example) as inspection of the mother substrate 200 described above.

As each region marked with “×”, a region of the peripheral region 202 is selected, where light-shielding materials such as circuits, wiring lines, alignment marks, etc., are not formed. Then, a dummy partition 6 similar to the partition 6 formed in the panel regions 201 is formed in the regions marked with “×”, and the image of the dummy partition 6 is captured with the length-measuring machine camera 100, thereby measuring the protrusion amount D. In this manner, the protrusion amount D of the partition 6 can be measured without being affected by the light-shielding material.

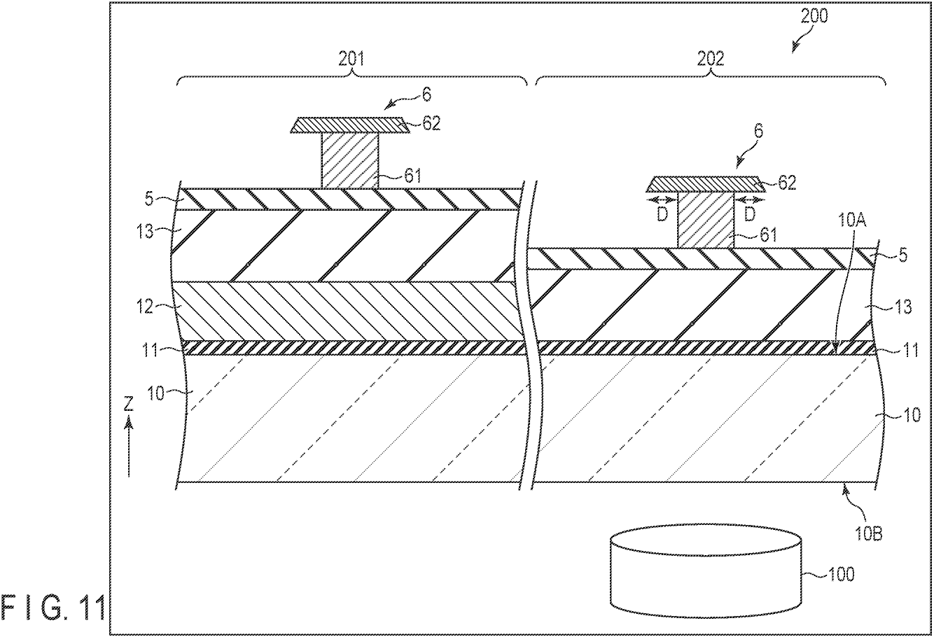

Now, a manufacturing method (manufacturing process) for the display device DSP according to this embodiment will be described with reference to FIG. 11.

First, a mother base (hereinafter referred to as “mother base 10” for convenience) is prepared, on which a plurality of bases 10 are formed at once, and then an insulating layer 11 is formed on the mother base 10 in the panel regions 201 and the peripheral region 202. Next, in the panel regions 201, a circuit layer 12 is formed on the insulating layer 11. Note here that no display panel is formed in the peripheral region 202 (that is, no pixels are present), and therefore the circuit layer 12 including circuits and wiring lines to drive pixels is not formed in the peripheral region 202.

Further, in the panel regions 201, the insulating layer 13, the rib 5 and the partition 6 (the lower portion 61 and the upper portion 62) are formed in order on the circuit layer 12. Similarly, in the peripheral region 202, the insulating layer 13, the rib 5 and the partition 6 (the lower portion 61 and the upper portion 62) are formed in order on the insulating layer 11.

Let us suppose here that the insulating layer 11, the insulating layer 13, the rib 5 and the partition 6 described above are formed by the same process in the panel regions 201 and peripheral region 202. Although omitted from the illustration of FIG. 11, the lower electrode LE formed in the panel regions 201 need not be formed in the peripheral region 202.

When the partition 6 is formed as described above, the image of the partition 6 is captured from a side of a second surface 10B (a surface on a side where the display element 20, etc., is not disposed) opposing a first surface 10A of the mother base 10 using the length-measuring machine camera 100, in the peripheral region 202, thereby making it possible to measure the protrusion amount D of the partition 6. When the protrusion amount D of the partition 6 thus measured using the length-measuring machine camera 100 is appropriate, the display element 20 is formed as described in FIGS. 5 to 7 above. Thereafter, the display panels formed respectively in the panel regions 201 are cut from the mother substrate 200, and using a cut display panel, the display device DSP is manufactured.

Whether or not the protrusion amount D of the partition 6 measured using the length-measuring machine camera 100 is appropriate can be determined, for example, by a manager or the like involved in the manufacture of the display device DSP. Further, in order to assist the manager in determining whether the protrusion amount D of the partition 6 is appropriate or not, the length-measuring machine camera 100 or an electronic device connected to the length-measuring machine camera 100 may as well be used, that outputs an alert when the measured protrusion amount D of the partition 6 does not fall within a predetermined range (that is, the protrusion amount D is not appropriate), for example.

The protrusion amount D of the partition 6 to be measured using the length-measuring machine camera 100 may be a distance (length) along the first direction X and the second direction Y, or a distance (length) along one of the first direction X and the second direction Y.

Further, although a detailed description thereof will be omitted, the partition 6 in this embodiment is formed by, for example, carrying out isotropic wet etching after carrying out anisotropic dry etching on the lower portion 61 and the upper portion 62. Here, this embodiment has the structure of measuring the protrusion amount D of the partition 6 in order to suppress the degradation in reliability of the display device DSP (display panel). Therefore, if a partition 6 having different protrusion amounts D between the panel regions 201 and the peripheral region 202 is formed, the significance of measuring the protrusion amount D in the peripheral region 202 is reduced.

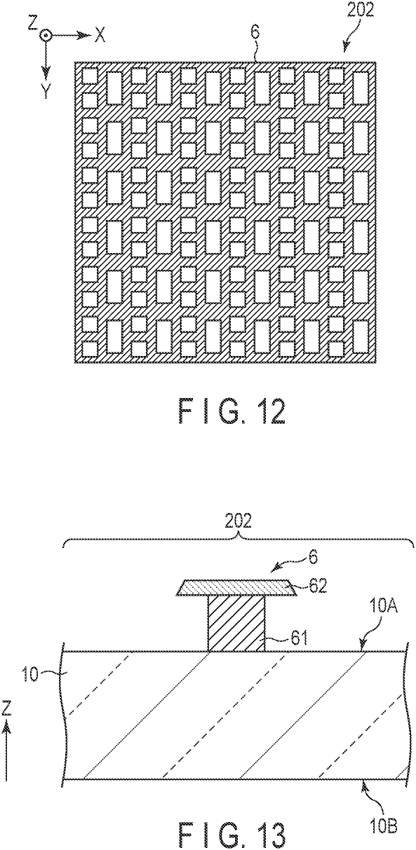

Therefore, in this embodiment, in order to equalize the variation in the etching amount during the formation of the partition 6 in the panel regions 201 and the peripheral region 202 (that is, to equalize the protrusion amount of the upper portion 61 of the partition of the panel regions 201 and the protrusion amount of the upper portion 61 of the partition of the peripheral region 202), a partition 6 of the same pattern as that of the partition 6 in the panel regions 201 is supposed to be formed in at least in the regions marked with “×” in the peripheral region 202. More specifically, in the panel regions 201, the partition 6 is formed in a pattern identical to that compartmentalizing the subpixels SP, and in the peripheral region 202, similarly, the partition 6 is supposed to be formed in a pattern identical to that compartmentalizing the subpixel SP as shown in FIG. 12, for example.

Note that in order to form the partition 6 having a corresponding shape in each of the panel regions 201 and the peripheral region 202, the peripheral region 202 (the region where the protrusion amount D of the partition 6 is measured) should preferably have such a width that at least a plurality of pixels PX (subpixels SP) are compartmentalized from each other. In the example illustrated in FIG. 12, it is assumed that the partition 6 is formed into a pattern that compartmentalizes the pixels PX (the subpixels SP1, SP2 and SP3) in the number of 36 (6 × 6 = 36) in the regions marked with “×” in the peripheral region 202. Note here that in the regions marked with “×”, for example, the partition 6 may be formed into a pattern that compartmentalize a number of pixels PX in the number such as 100 (10 × 10 = 100). The rib 5 in the peripheral region 202 may be formed in the same pattern as that of the panel regions 201, or may be formed in a pattern different from that of the panel regions 201.

Further, this embodiment is described in connection with the case where the protrusion amount D of the partition 6 formed in the peripheral region 202 is measured. Note here that it is preferable that the measurement of the protrusion amount D of the partition 6 be carried out in all of the regions marked with “×” shown in FIG. 10 while, for example, moving the length-measuring machine camera 100. With this operation, it is considered to be able to improve the reliability of all display panels (the display devices DSP manufactured therefrom) formed in the plurality of panel regions 201 of the mother substrate 200.

Note here that in order to reduce the load on the measurement of the protrusion amount D of the partition 6, the protrusion amount D of the partition 6 may be measured in some of the regions marked with “×” shown in FIG. 10. In this case, the protrusion amount D of the partition 6 may be measured, for example, in the regions near the four corners of the mother substrate 200 and in the region near the center of the mother substrate 200.

As described above, this embodiment has such a structure that the protrusion amount D of the partition 6 disposed on the first surface 10A of the base 10 (that is, the distance between the side surface of the lower portion 61 and the end portion of the upper portion 62 of the partition 6) is measured from a side of the second surface 10B of the base 10, and therefore the display device DSP can be manufactured in a state where the protrusion amount D is appropriate. Thus, it is possible to suppress the deterioration of the reliability of the display device DSP.

Note that in this embodiment, a mother base 10 including a plurality of panel regions 201 and a peripheral region 202 which compartmentalizes the panel regions 201 from each other is prepared. In the plurality of panel regions 201, an insulating layer 11 (a first insulating layer) is formed on the first surface 10A of the mother base 10, and on the insulating layer 11, a circuit layer 12 including pixel circuits that drives subpixels SP (pixels) is formed. Then, an insulating layer 13 (a second insulating layer) is formed on the circuit layer 12, and a lower electrode LE is formed in a position overlapping the respective subpixel SP on the insulating layer 13. A rib 5 that covers a part of the lower electrode LE and compartmentalizes the subpixels SP is formed, and thus a partition 6 is formed over the rib 5. On the other hand, in the peripheral region 202, the insulating layer 11 is formed on the first surface 10A of the mother base 10, the insulating layer 13 is formed on the insulating layer 11, the rib 5 is formed on the insulating layer 13, and the partition 6 is formed on the rib 5. In this case, the protrusion amount D of the partition 6 formed in the peripheral region 202 is measured. With this configuration, even if it is difficult to accurately measure the protrusion amount D of the partition 6 in the panel regions 201 due to the influence of the circuit layer 12, etc., the protrusion amount D can be measured by utilizing the peripheral region 202 where the circuit layer 12 is not formed.

Further, in this embodiment, respective partitions 6 in the panel regions 201 are formed in a pattern that compartmentalizes the subpixels SP. In contrast, the partition 6 in the peripheral region 202 is formed in a pattern identical to that of the partitions 6 formed in the panel regions 201 (that is, it is formed as a dummy pattern that imitates the subpixels SP). With this structure, the variation between the etching amount when forming the partitions 6 in the panel regions 201 and the etching amount when forming the partition 6 in the peripheral region 202 can be reduced. Therefore, it is possible to determine whether or not the partitions 6 are properly formed in the panel regions 201 by measuring the protrusion amount D of the partition 6 formed in the peripheral region 202.

Incidentally, this embodiment is described in connection with the case where the protrusion amount D of the partition 6 formed in the peripheral region 202 is measured, for example, as described in FIG. 11, but note that due to the influence of the staked multiplayer film located underneath the partition 6 (namely, the insulation layer 11, the insulation layer 13 and the rib 5 between the mother base 10 and the partition 6), it may be difficult to capture images of the partition 6 (the lower portion 61 and the upper portion 62) with the length-measuring machine camera 100. In such cases, the protrusion amount D of the partition 6 may not be measured accurately (that is, the measurement accuracy of the protrusion amount D of the partition 6 may decrease).

Therefore, this embodiment may employ such a structure that at least one of the insulating layer 11, the insulating layer 13 and the rib disposed between the mother base 10 and the partition 6 in the peripheral region 202 may be removed (omitted). More specifically, in the peripheral region 202, the partition 6 may be formed directly on the mother base 10 as shown in FIG. 13.

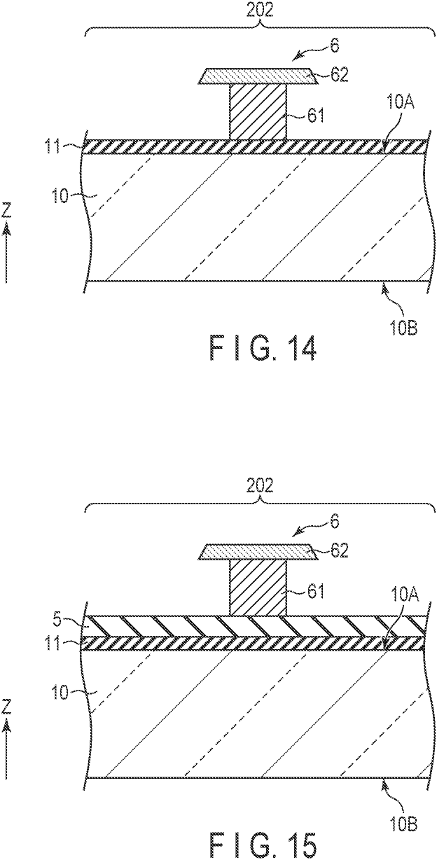

Note that as for the layers to be patterned in the panel regions 201 (for example, the insulating layer 13 in which contact holes CH are formed and the rib 5 that compartmentalizes the subpixels SP from each other), it is considered relatively easy to remove these layers from the peripheral region 202 by etching. On the other hand, as for layers that are not etched in the panel regions 201 (for example, the insulating layer 11 and the like), it is necessary to carry out etching only on the peripheral region 202 in a separated step so as to remove the layers from the peripheral region 202. Therefore, from the viewpoint of controlling the manufacturing costs, the peripheral region 202 may have a structure in which the insulating layer 11 (the first insulating layer) and the partition 6 are formed in order on the mother base 10 (that is, a structure in which the insulating layer 13 and the rib 5 are removed) as shown in FIG. 14, without carrying out etching of the insulating layer 11.

Further, the insulating layer 13 may be formed of an organic material such as polyimide colored yellow or the like, and therefore the accuracy of measurement of the protrusion amount D of the partition 6 using the length-measuring machine camera 100 may be reduced. According to this viewpoint, it is desirable that the insulating layer 13 be removed between the mother base 10 and the partition 6 in the peripheral region 202. For example, the peripheral region 202 may have a structure in which the insulating layer 11 (the first insulating layer), the rib 5 and the partition 6 are formed in order on the mother base (the base 10) (that is, the structure in which the insulating layer 13 is removed) as shown in FIG. 15.

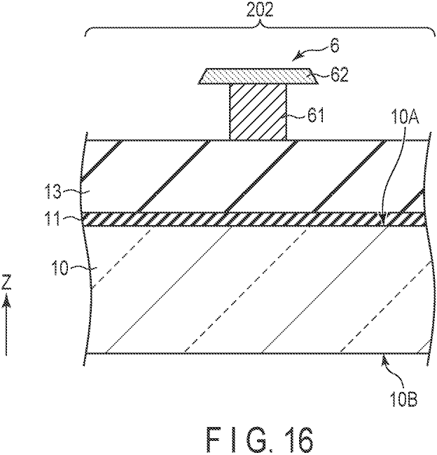

Note that the rib 5, for example, is formed of an inorganic material such as silicon nitride having a relatively high refractive index. Therefore, from the viewpoint of suppressing undesired refraction caused by the difference in refractive index from that of other materials in contact with the rib 5, the peripheral region 202 may have a structure, as shown in FIG. 16, in which the insulating layer 11 (the first insulating layer), the insulating layer 13 (the second insulating layer) and the partition 6 are formed in this order (that is, the structure in which the rib 5 is removed).

That is, from the viewpoint of the accuracy of measurement of the protrusion amount D of the partition 6 as described above, it is preferable to remove all of the insulating layer 11, the insulating layer 13 and the rib 5 in the peripheral region 202. But if, for example, it is impossible to remove all of the layers, at least one of the insulating layer 11, the insulating layer 13 and the rib 5 may be provided between the mother base 10 and the partition 6. More specifically, in this embodiment, it suffices if the peripheral region 202 is configured such that the protrusion amount D of the partition 6 can be measured using the length-measuring machine camera 100, and the layer structure between the mother base 10 and the partition 6 in the peripheral region 202 can be changed as needed. According to this, although not included in the examples shown in FIGS. 11 to 16, the peripheral region 202 may have a structure in which, for example, only the insulating layer 11 of the insulating layer 11, the insulating layer 13 and the rib 5 is removed.

Note that this embodiment is assumed on the case where the upper portion 62 of the partition 6 is formed of a light-shielding material (for example, a metal material) that does not have light transparency, and the protrusion amount D of the partition 6 is measured from a side of a second surface 10B of the mother base 10. Here, for example, if the upper portion 62 is formed of a transparent material that has light transparency, such a structure may as well do that the protrusion amount D of the partition 6 is measured from a side of the first surface 10A of the mother base 10 (that is, from a side of the display surface of the display device DSP).

All manufacturing methods for display devices and mother substrates, which are implementable with arbitrary changes in design by a person of ordinary skill in the art based on the manufacturing methods for display devices and mother substrates described above as the embodiments of the present invention, belong to the scope of the present invention as long as they encompass the spirit of the present invention.

Various modifications are easily conceivable within the category of the idea of the present invention by a person of ordinary skill in the art, and these modifications are also considered to belong to the scope of the present invention. For example, additions, deletions or changes in design of the constituent elements or additions, omissions or changes in condition of the processes may be arbitrarily made to the above embodiments by a person of ordinary skill in the art, and these modifications also fall within the scope of the present invention as long as they encompass the spirit of the present invention.

In addition, the other advantages of the aspects described in the above embodiments, which are obvious from the descriptions of the specification or which are arbitrarily conceivable by a person of ordinary skill in the art, are considered to be achievable by the present invention as a matter of course.

What is claimed is:

1. A method of manufacturing a display device, comprising:
forming a partition including a lower portion disposed on a first surface of a base and an upper portion protruding from a side surface of the lower portion; and
measuring a distance between a side surface of the lower portion and an end portion of the upper portion from a side of a second surface opposing the first surface of the base.

2. The method of claim 1, wherein,
the base includes a plurality of panel regions in which display panels are formed and a peripheral region that compartmentalizes the plurality of panel regions,
the partition is formed in both the plurality of panel regions and the peripheral region, and
the measuring is carried out by capturing an image of the partition formed in the peripheral region from a side of the second surface with a length-measuring machine camera.

3. The method of claim 2 further comprising:
forming a first insulating layer on a first surface of the base prior to the forming of the partition; and
forming a circuit layer including a pixel circuit that drives a pixel on the first insulating layer, forming a second insulating layer on the circuit layer, forming a lower electrode at a position overlapping the pixel on the second insulating layer, and forming a rib covering a part of the lower electrode and compartmentalizing the pixel, in the plurality of panel regions, wherein
the forming of the partition includes forming the partition on the rib in the plurality of panel regions and on a first surface of the base in the peripheral region.

4. The method of claim 2, wherein
in the plurality of panel regions, the partition is formed in a pattern that compartmentalizes the pixel,
in the peripheral region, the partition is formed in a pattern identical to that of the partition formed in the plurality of panel regions.

5. The method of claim 3, wherein
in the peripheral region, at least one of the first insulating layer, the second insulating layer and the rib is formed between the base and the partition.

6. The method of claim 3 further comprising:
forming an organic layer on the lower electrode after the measuring;
forming an upper electrode on the organic layer;
forming a cap layer on the upper electrode;
forming a sealing layer on the cap layer;
forming a resist on the sealing layer; and
removing the sealing layer, the cap layer, the upper electrode and the organic layer using the resist as a mask.

7. The method of claim 1, wherein
the partition is formed by carrying out isotropic wet etching after carrying out anisotropic dry etching.

8. The method of claim 1, wherein
the upper portion of the partition is formed of a light-shielding material.

9. A mother substrate comprising:
a base including a plurality of panel regions in which display panels are formed and a peripheral region that compartmentalizes the plurality of panel regions;
a first insulating layer disposed on a first surface of the base;
a circuit layer disposed on the first insulating layer and including a pixel circuit configured to drive a pixel in the plurality of panel regions;
a second insulating layer disposed on the circuit layer;
a lower electrode disposed at a position overlapping the pixel on the second insulating layer; and
a rib covering a part of the lower electrode and compartmentalizing the pixel; and
a partition disposed on the rib in the plurality of panel regions and in the peripheral region,
the partition including a lower portion and an upper portion protruding from a side surface of the lower portion.

10. The mother substrate of claim 9, wherein
the partition in the plurality of panel regions is disposed in a pattern that compartmentalizes the pixel, and
the partition in the peripheral region is disposed in a pattern identical to that of the partition in the plurality of panel regions.

11. The mother substrate of claim 10, wherein
a protrusion amount of the upper portion of the partition in the plurality of panel regions is equivalent to a protrusion amount of the upper portion of the partition in the peripheral region.

12. The mother substrate of claim 9, wherein
at least one of the first insulating layer, the second insulating layer and the rib is disposed between the base and the partition in the peripheral region.

13. The mother board of claim 9, wherein
the upper portion of the partition is formed of a light-shielding material.

14. The mother substrate of claim 9 further comprising:
an organic layer disposed on the lower electrode; an upper electrode disposed on the organic layer and in
contact with the lower portion of the partition; a cap layer disposed on the upper electrode; and
an sealing layer disposed on the cap layer.
